(19) United States
(12) Patent Application Publication
(10) Pub. No.: US 2025/0100264 A1
(43) Pub. Date: Mar. 27, 2025

(54) LAMINATOR APPARATUS AND METHOD OF MAKING CURVED LAMINATED SOLAR PANEL

(71) Applicant: APTERA MOTORS CORP., Carlsbad, CA (US)

(72) Inventors: Anuj M. THAKKAR, Carlsbad, CA (US); Nathan T. ENGLER, Carlsbad, CA (US); Reed THURBER, Carlsbad, CA (US); Jesse H. WOOD, Carlsbad, CA (US)

(73) Assignee: APTERA MOTORS CORP., Carlsbad, CA (US)

(21) Appl. No.: 18/852,227

(22) PCT Filed: Mar. 18, 2023
(86) PCT No.: PCT/US2023/064679

§ 371 Date: Sep. 27, 2024

Related U.S. Application Data
(60) Provisional application No. 63/321,627, filed on Mar. 18, 2022.

(51) Int. Cl. B32B 37/10; B32B 37/12; H10F 19/80; H10F 71/00

(52) U.S. Cl. CPC B32B 37/1018; B32B 37/12; H10F 19/80; H10F 71/00; B32B 2457/12

(57) ABSTRACT

An apparatus, system and method for a laminator is disclosed capable of producing a doubly curved solar panel with doubly curved solar cells. The laminator panel comprises a housing divided into lower and upper chambers by a membrane, the lower housing comprising a convex surface in the form of a mold and/or tray in the desired panel shape. The convex surface is of a shape that induces gentle curvature in the membrane at the panel edge under lamination conditions. The tray may include holes at the panel edge for evacuation of encapsulant vapors while the mold includes channels in communication with the vacuum for collecting the vapors. The housing is configured to prevent overextension of the membrane. Lift pins provide insulation from the heated convex surface. A lamination method is provided wherein a lamination stack may be secured to itself and to the convex surface with removable adhesive tape.

### CROSS-REFERENCE TO RELATED APPLICATION

This application claims priority to, and the benefit of, co-pending U.S. Provisional Patent Application No. 63/321,627, filed on Mar. 18, 2022, entitled “Laminator Apparatus And Method Of Making Curved Laminated Solar Panel”, which is incorporated by reference in its entirety.

### TECHNICAL FIELD

The invention relates generally to a laminator apparatus for the manufacturing of multi-dimensional laminated products. In particular, the invention relates to an apparatus, system, and method of manufacturing of a laminated solar panel product having two axes of curvature.

### BACKGROUND

In the field of solar electric vehicles, the use of solar panels presents a challenge as a desirable body design typically includes complex geometry, such as the surface of the roof, hood, or trunk. Solar panels with a complex geometry are challenging to build for a variety of reasons. During the manufacturing process—and during lamination in particular—a primary reason for failure is the stress caused by simple or complex bending, torsion, or other deformation which exceeds the ultimate strength of the semiconductor material. For example, the forced deformation of silicon cells to synclastic panel surfaces leads to particularly high internal stresses that may lead to brittle fracture or premature failure. For these and other reasons, it is difficult to achieve a low failure rate in laminating of solar cells into complex panel shapes, and difficult to do in a high-volume, high-yield manner.

Despite strong incentives across a variety of industries, there remains a long-felt need for a laminator for manufacturing a doubly curved solar panel with doubly curved solar cells.

Laminators capable of producing curved panels have common elements with flat panel laminators, including features that supply heat, vacuum and pressure. Applying a uniform pressure is particularly important, and for this a deformable, elastic membrane is typically used. For curved laminators, an apparatus for or method of imparting or retaining a precise shape is also necessary. For this either a curved mold or a thin, curved tray or both is typically used. However, an issue arises when an elastic membrane is stretched over a curved panel surface. When the deformation of the membrane is high at the panel edge and the thickness of the panel is non-negligible a sharp change in orientation of the membrane can lead to local pressure non-uniformities and panel deformation. Such panel deformation can lead to incomplete outgassing, bubble formation, improper curing, edge delamination and panel failure. Therefore, it is important to manage the orientation of the membrane at the panel edge to prevent non-uniform pressure zones.

In a similar issue, membrane-based laminators are subject to membrane failure over multiple lamination cycles wherein the membrane is forced into sharp corners or edges of the lamination chamber. When conforming to these features the membrane is overextended and can develop cracks and tears.

To reduce the lamination cycle time in a mold-based laminator, the mold is kept at the lamination temperature, thereby avoiding extended thermal ramp times and increasing energy efficiency. However, it would be extremely challenging to layup the lamination materials on such a heated surface. Therefore, it is desirable to prepare the lamination stack separately and load it into the chamber as a unit. Furthermore, in order to allow vacuum to be established in the lower chamber, it is desirable to keep the lamination stack a short distance from the mold thereby keeping it at a controlled temperature before lowering it onto the mold. This is typically achieved with lift pins embedded in the mold. However, the pins are commonly made of stainless steel, aluminum or other metal and are thermally conductive. As a result, the area of the lamination stack that is near the lift pins may see a slightly higher temperature than the surrounding layers and begin curing prematurely. This may result in a non-uniform curing of the panel.

It is often the case in a lamination process that the encapsulation or “glue” layers contain volatile species that must be evacuated from the film in order for the layer to cure. Trapping of volatile components can lead to bubble formation, incomplete cure, delamination and panel failure. A major cause of trapped gasses is sealing of the panel edge against the mold by the membrane leaving no egress to the vacuum side of the laminator.

In the lamination process it is essential that during the curing phase the temperature of the tray is uniform and well controlled. For a laminator wherein both a tray and a mold are used, the primary means of heating the tray is via conduction through the mold. Therefore, uniform physical contact between the tray and the mold is paramount. However, the tray and lamination stack are loaded into the laminator at ambient temperature, while the mold is kept at an elevated temperature. Therefore, if the tray dimensions match the mold at ambient temperature, the tray will necessarily be small relative to the mold when the tray is loaded. Furthermore, if the geometry of the tray and mold includes opposing vertical interfaces, then the tray will not fit the mold until it reaches the temperature of the mold. This may require an excessive amount of time if the tray sits above the mold and is heated by convection and/or radiation only. A better system is needed.

Body panels for automobiles are manufactured to a tolerance of approximately +1 mm. The same tolerance must be met for solar enabled body panels with a variety of metallic and non-metallic materials incorporated therein. The heterogeneous nature of a solar panel makes this a challenge for a variety of reasons. First, instead of a monolithic sheet of metal, multiple layers of disparate materials and different sizes must be joined to make a solar panel. This, in turn, requires that they be aligned to one another such that there is a single, uniform edge, so that the protective edging may be assembled to it, so that it mates properly with a frame, so that electrical feedthroughs may be populated with short conductors, so that printed patterns do not overlay solar cells, and so forth. A robust alignment system and method is therefore required for manufacturability. The system and/or method may be different for low volume vs. high volume production.

Complicating the fabrication of solar enabled body panels is the thermal profile of the lamination process. Because the materials involved have vastly different coefficients of thermal expansion (CTEs) the lamination stack will want to expand or contract relative to the tray or mold. For example, as the temperature increases polymer materials will expand relative to an aluminum tray, whereas glass materials will contract. Furthermore, the application of pressure via the membrane may induce a translation of the superstrate relative to the substrate resulting in misalignment. For these reasons, a robust alignment maintenance scheme is required for manufacturability. The system and/or method may be different for low volume vs. high volume production.

### SUMMARY

The present invention advantageously addresses the aforementioned deficiencies by providing a laminator apparatus, system, and method for manufacturing a doubly curved solar panel with doubly curved solar cells, the laminator being capable of continuous output. In one embodiment, the laminator comprises a clamshell laminator apparatus, system, and lamination method. In another embodiment, the laminator comprises a vertical upstroke press apparatus, system, and lamination method. This disclosure, and the concepts elaborated upon herein, may apply to either type of laminator, a clamshell or a vertical upstroke press, unless otherwise specified.

It is an object of this disclosure to provide a mold and/or tray design to minimize pressure non-uniformities caused by membrane bending at the curved panel edge.

It is an object of this disclosure to provide a means of preventing premature failure of the membrane caused by overextension into sharp corners and edges of the lamination chamber(s).

It is an object of this disclosure to provide a means for reducing thermal communication between the lift pins and the thermal stack in a mold-based laminator to ensure more spatially uniform curing.

It is an object of the present disclosure to provide a means for evacuating gasses otherwise trapped by the membrane as it seals the panel against the tray and/or mold.

It is an object of the present disclosure to provide a means for retaining alignment and uniform thermal contact between the tray and mold during the temperature ramp-up of the tray.

It is an object of this disclosure to provide a robust system and method for alignment of the lamination stack.

It is an object of this disclosure to provide a robust system and method for maintaining the alignment of the lamination stack and tooling during the lamination process.

Other desirable features and characteristics will become apparent from the subsequent detailed description, the drawings, and the appended claims, when considered in view of this summary.

### DESCRIPTION OF THE DRAWINGS

Non-limiting and non-exhaustive embodiments of the present invention are described with reference to the following drawings. In the drawings, like numerals describe like components throughout the several views.

For a better understanding of the present invention, reference will be made to the following Detailed Description, which is to be read in association with the accompanying drawings, which are incorporated in and constitute a part of this specification, show certain aspects of the subject matter disclosed herein, and, together with the description, help explain some of the principles associated with the disclosed implementations, wherein:

FIG. 1A illustrates a perspective view of a doubly curved solar panel incorporating doubly curved solar cells, according to an embodiment of the present invention;

FIG. 1B illustrates an enlarged view of FIG. 1A, according to an embodiment of the present invention;

FIG. 2A illustrates a perspective view of a flanged doubly curved solar panel incorporating doubly curved solar cells, according to an embodiment of the present invention;

FIG. 2B illustrates a section view of FIG. 2A, according to an embodiment of the present invention;

FIG. 2C illustrates a detail view of FIG. 2B, according to an embodiment of the present invention;

FIG. 3A illustrates a perspective view of a vertical upstroke press laminator, according to an embodiment of the present invention;

FIG. 3B illustrates a perspective view of a clamshell laminator, according to an alternative embodiment of the present invention;

FIG. 4A illustrates a perspective view of a mold with heating elements, according to an embodiment of the present invention;

FIG. 4B illustrates a perspective view of an upper housing with heating elements, according to an embodiment of the present invention;

FIG. 5A illustrates a perspective view of upper and lower trays with heating elements disposed on the upper tray, according to an embodiment of the present invention;

FIG. 5B illustrates a section view of FIG. 5A, according to an embodiment of the present invention;

FIG. 6A illustrates a section view of a lamination stack with temporary alignment binders, according to an embodiment of the present invention;

FIG. 6B illustrates a section view of a laminator in a loading/unloading configuration with thermally isolated lift pins, according to an embodiment of the present invention;

FIG. 7A illustrates a section view of an open laminator with exploded view laminate stack and lift pins in a load position, according to an embodiment of the present invention;

FIG. 7B illustrates a section view of a closed laminator with laminate stack in an evacuation and preheat configuration, according to an embodiment of the present invention;

FIG. 7C illustrates a section view of a closed laminator with laminate stack in a lamination configuration, according to an embodiment of the present invention;

FIG. 7D illustrates a section view of an open laminator with laminated panel, trays and lift pins in an unload position, according to an embodiment of the present invention;

FIG. 8 illustrates exemplary process steps pertaining to a laminator capable of forming laminates into a doubly curved solar panel, according to an embodiment of the present invention;

FIG. 9A illustrates a section view of a rounded mold and unpressurized membrane, according to physics;

FIG. 9B illustrates a section view of a rounded mold and lightly pressurized membrane, according to physics;

FIG. 9C illustrates a section view of a rounded mold and moderately pressurized membrane, according to physics;

FIG. 9D illustrates a section view of a rounded mold and heavily pressurized membrane, according to physics;

FIG. 10A illustrates a partial section view of a rounded mold and fully pressurized membrane, according to physics;

FIG. 10B illustrates a partial section view of a rounded mold with lamination stack and lightly pressurized membrane, according to physics;

FIG. 10C illustrates a partial section view of a rounded mold with lamination stack and moderately pressurized membrane, according to physics;

FIG. 11A illustrates a section view of a mold with an obtuse angle at the solar panel edge and a fully pressurized membrane, according to an embodiment of the present invention;

FIG. 11B illustrates a section view of a mold with a panel recess and a fully pressurized membrane, according to an embodiment of the present invention;

FIG. 11C illustrates a section view of a tray with a stamped panel recess, a mold with a matching machined recess and a fully pressurized membrane, according to an embodiment of the present invention;

FIG. 11D illustrates a section view of a tray with stamped panel risers, a smooth mold and a fully pressurized membrane, according to an embodiment of the present invention;

FIG. 11E illustrates a section view of a tray with assembled panel risers, a smooth mold and a fully pressurized membrane, according to an embodiment of the present invention;

FIG. 12A illustrates a section view of a tray with vertical sidewalls at ambient temperature, a mold with vertical sidewalls at elevated temperature and a fully pressurized membrane, according to an embodiment of the present invention;

FIG. 12B illustrates a section view of a tray with vertical sidewalls, a mold with matching vertical sidewalls, both at elevated temperature, and a fully pressurized membrane, according to an embodiment of the present invention;

FIG. 13A illustrates a section view of a tray with angled sidewalls at ambient temperature and a mold with angled sidewalls at elevated temperature, according to an embodiment of the present invention;

FIG. 13B illustrates a section view of a tray with angled and a mold with angled sidewalls both at elevated temperature, according to an embodiment of the present invention;

FIG. 14A illustrates a section view of a tray with vertical sidewalls and compliant alignment features at ambient temperature and a mold with vertical sidewalls at elevated temperature, according to an embodiment of the present invention;

FIG. 14B illustrates a section view of a tray with vertical sidewalls and compliant alignment features and a mold with vertical sidewalls both at elevated temperature, according to an embodiment of the present invention;

FIG. 15A illustrates a section view of a laminator with membrane pulled by vacuum into an angular upper chamber, according to the prior art;

FIG. 15B illustrates a section view of a laminator with membrane pulled by vacuum into an angular lower chamber, according to the prior art;

FIG. 16A illustrates a section view of a laminator with membrane pulled by vacuum into a filleted upper chamber, according to an embodiment of the present invention;

FIG. 16B illustrates a section view of a laminator with membrane pulled by vacuum into a filleted lower chamber, according to an embodiment of the present invention;

FIG. 17A illustrates a section view of a laminator with slack membrane resting a mold, according to an embodiment of the present invention;

FIG. 17B illustrates a section view of a laminator with slack membrane membrane pulled by slight vacuum into an upper chamber, according to an embodiment of the present invention; and

FIG. 18 illustrates a section view of a tray with stamped panel recess and vent holes near the panel edge and a mold with vent channels, according to an embodiment of the present invention.

### DETAILED DESCRIPTION

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as limitation thereto.

The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The drawings featured in the figures are provided for the purposes of illustrating some embodiments of the present invention and are not to be considered as limitation thereto. The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

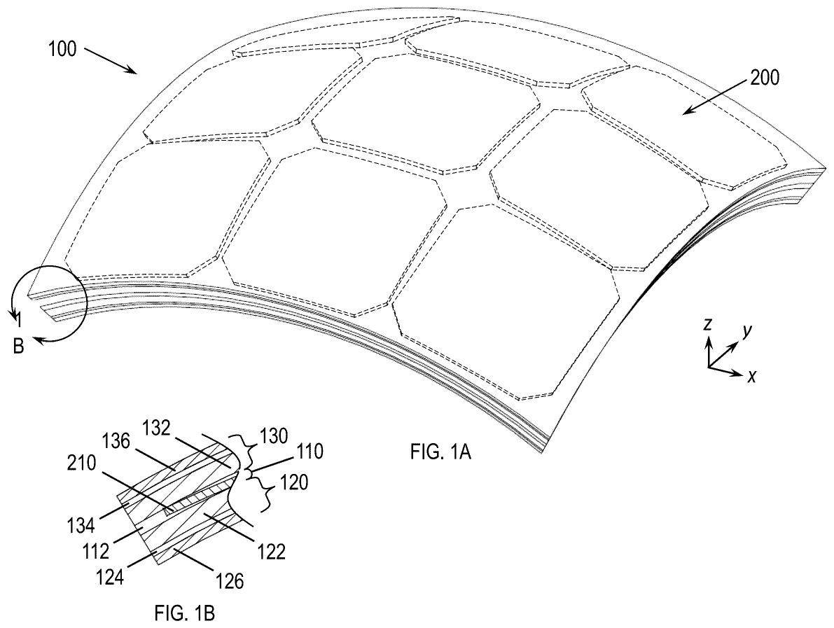

An exemplary laminated solar panel 100, illustrated in FIGS. 1A and 1B, comprises a solar cell array 200 encased in a plurality of polymer layers. The solar panel may be curved about two axes, x and y. The radii of curvature about each axis in one or more portions of the panel are such that the cells 210 of the solar cell array 200 must bend in two directions. Moreover, the panel 100 may be non-uniformly curved, for example, having more curvature in some portions relative to others. A doubly curved laminated solar panel 100 can be manufactured according to the disclosure of co-pending patent application Ser. No. 18/169,576, filed on Feb. 15, 2023 entitled Curved Laminated Solar Panel and Method of Manufacturing Thereof, which is incorporated herein by reference. Furthermore, a laminator used to manufacture a solar panel curved about one or more axes may be utilized in a continuous plant according to the disclosure of co-pending patent application Ser. No. 18/168,274, filed on Feb. 13, 2023 entitled Plant Providing Continuous Process for Making Laminated Solar Panels, also incorporated herein by reference.

The lamination, shown in the detail view of FIG. 1B, includes a plurality of polymer layers which serve a variety of purposes for the structure and function of the solar panel 100. At the bottom is a substrate 120 which includes one or more polymer layers that provide mechanical stiffness and a seal against water ingress. In this example, the substrate 120 comprises a flexible layer of ethylene tetrafluoroethylene (ETFE) 126, a flexible adhesive layer 124, and a rigid layer of polycarbonate (PC) 122. At the top is a superstrate 130 which includes one or more polymer layers that provide mechanical stiffness, a seal against moisture, and resistance to damage caused by impact. In this embodiment, the superstrate 130 comprises a rigid layer of PC 132, a flexible adhesive layer 134, and a flexible layer of ETFE 136. In general, the PC 122, 132 may be configured to provide mechanical stiffness and impact resistance; while the ETFE 126, 136 acts as a barrier to water ingress, reduces dirt accumulation and provides scratch resistance. In the center may be a core 110 comprising the cells 210 of the solar cell array 200 surrounded by a layer of flow-melt adhesive, such as polyolefin elastomers (POE) 112. The POE 112 acts as a barrier to water ingress and increases durability and reliability. In an alternative embodiment the substrate 120 and superstrate 130 may comprise a single layer of chemically or thermally strengthened glass. A lamination apparatus capable of producing such a solar panel 100 would be advantageous.

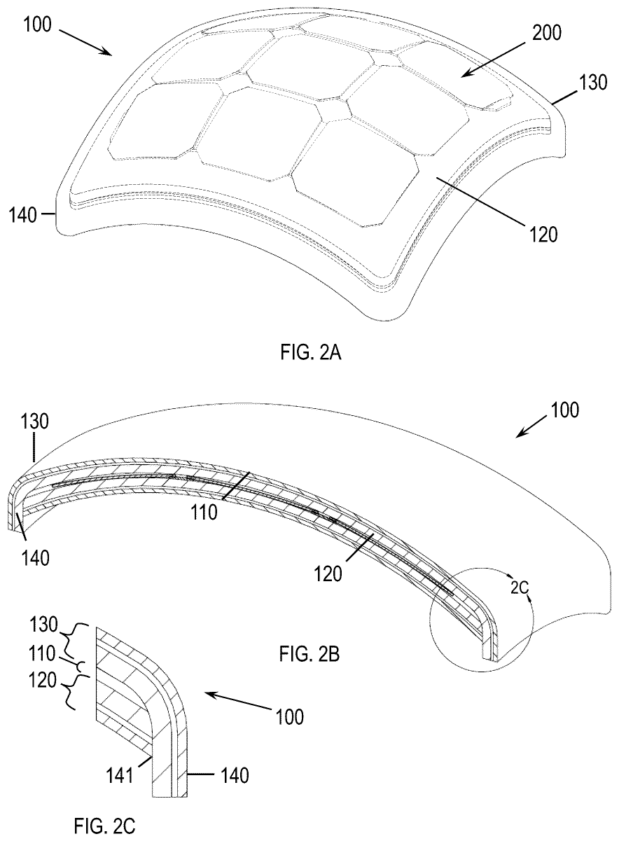

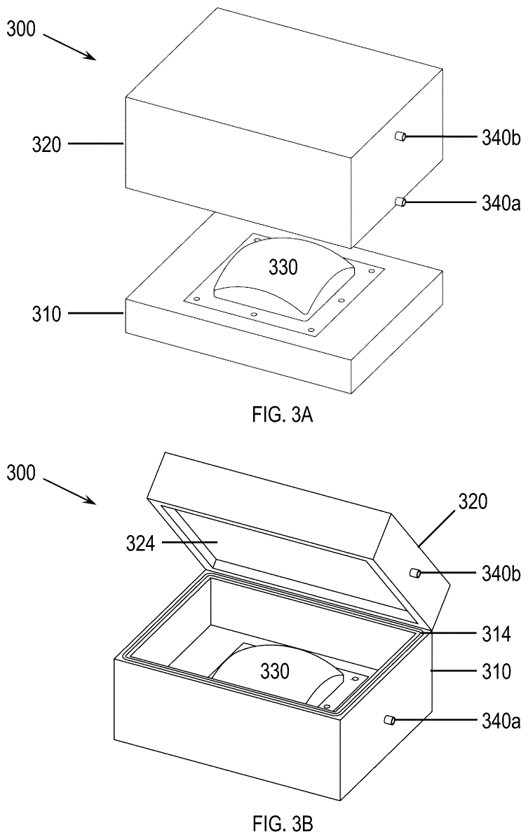

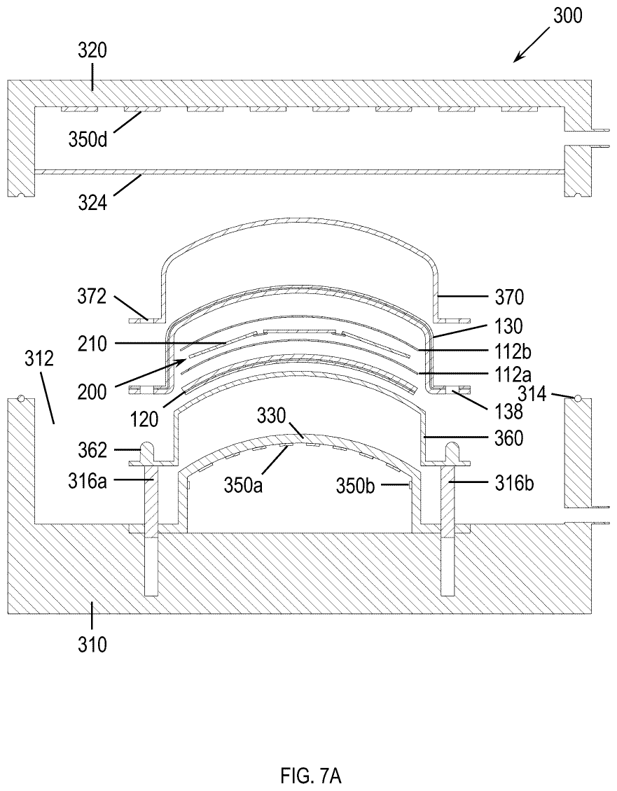

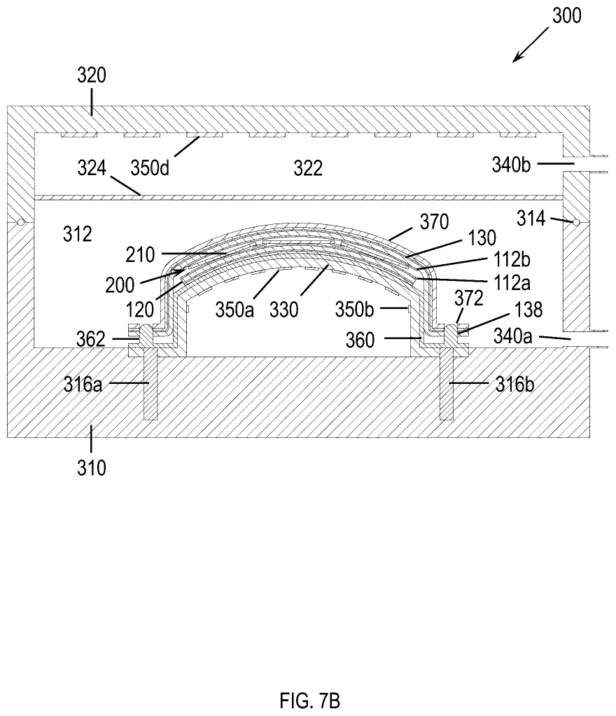

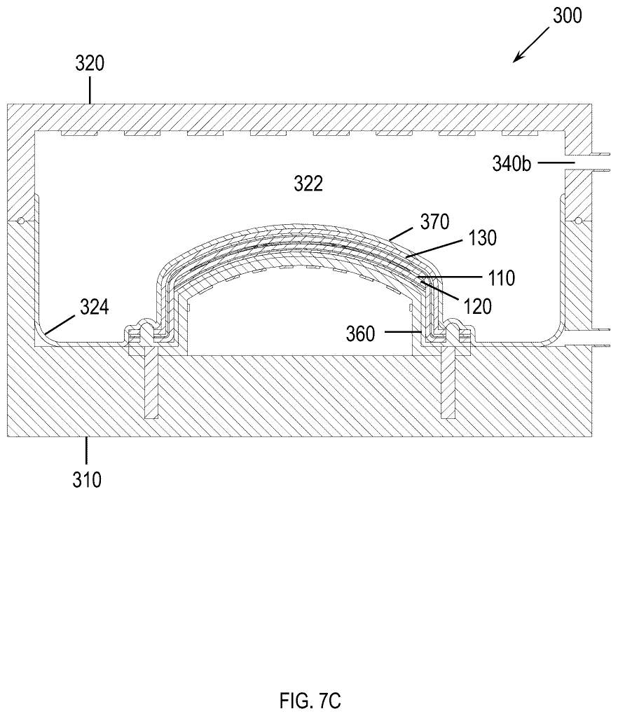

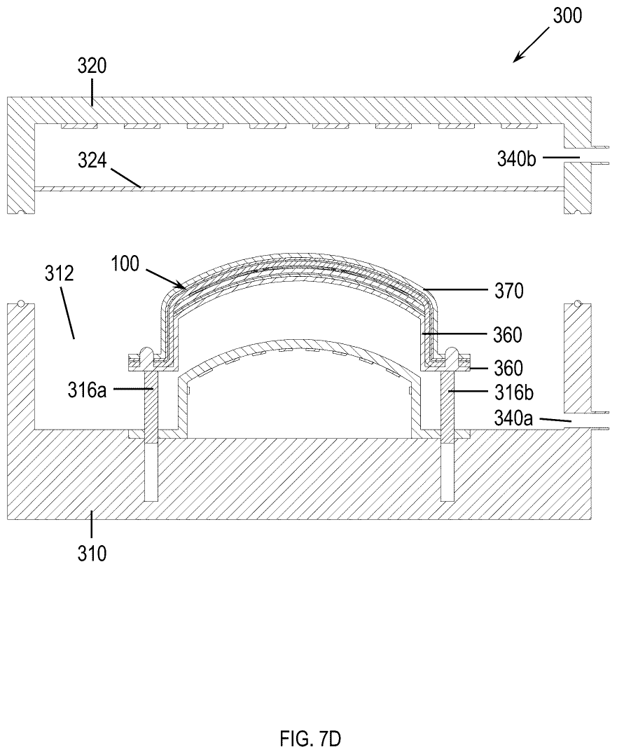

In some applications a flanged solar panel, as shown in FIGS. 2A and 2B, may be utilized and provide certain advantages. Referring to FIG. 2A, a solar panel 100 comprising a solar cell array 200 sandwiched by a substrate 120 and superstrate 130 further comprises a border that terminates in a flange 140. In this embodiment, shown in section and detail views in FIGS. 2B and 2C, the core 100 and substrate 120 are terminated by the superstrate flange 140 at an interface 141. A seal against water ingress and delamination for the core 110 and substrate 120 is thus integrally formed, though some water vapor transmission through the PC 132 may occur. A lamination apparatus capable of producing such a flanged solar panel 100 would therefore also be advantageous. Referring to FIGS. 3A and 3B, a laminator 300 is shown and described, wherein the output of the laminator 300 corresponds to the solar panel 100 previously described. FIG. 3A represents a vertical upstroke press laminator and FIG. 3B represents a clamshell laminator, either being representative of the present invention. The laminator 300 may comprise a lower housing 310 and an upper housing 320. When lower and upper housings 310, 320, are appropriately coupled, an enclosure is formed, as shown in, e.g., FIG. 7B, and which comprises both upper and lower chambers 312, 322. Lower and/or upper housings 310, 320, may further include first 340a and second ports 340b which may be configured to evacuate air from, or supply air to, the lower and/or upper chambers. Additional ports (not shown) may be disposed in lower and/or upper housings 310, 320 and configured to work in conjunction with one or more pumps and valves to achieve the desired conditions required for lamination, such as heating and/or pressurization of the lamination stack. Referring again to FIG. 3A, first and second housings 310, 320, are disposed in a vertically aligned, separated manner with respect to each other, so that a lamination stack may be loaded or conveyed into the first housing 310. In a vertical upstroke press embodiment, the lamination stack may be conveyed into the laminator 300, such as may be appropriate to form a continuous assembly in a manufacturing plant, and the first and second housing 310, 320, may be physically manipulated in any suitable manner, so that the lower housing may be sealed to form a chamber and so that corresponding vacuum to lower and upper chambers may be applied. For example, the entire assembly corresponding to the lower housing 310 and lamination stack may be urged towards the upper housing 320, the upper housing 320 being stationary. For another example, the mold 330 surface may be level with the top edge of the lower housing 310, so that the mold 330 protrudes out of the confinement of the lower chamber 312; this may be done to facilitate the conveyance of molds in and out of laminator 300.

The upper housing 320 may be further characterized by a membrane 324, or diaphragm, configured to provide separation between the upper and lower chambers 312, 322. The membrane 324 in this context may refer to a flexible membrane that is resistant to pressure and/or heat; the membrane 324 may be made of a rubber material such as silicone or other suitable material resistant to pressure and heat. In an alternate embodiment, the membrane 324 may be replaced by one or more pistons that, when actuated, engage the superstrate thereby applying pressure to the laminate stack. The lower housing 310 may be further characterized by a seal 314, such as an O-ring, and one or more lift pins 316 shown in FIG. 7B. Alternatively, the seal 314 may be coupled to the upper housing 320. The lower housing 310 may additionally be characterized by a mold 330. The mold 330 may be coupled to the lower housing 310 in any appropriate way; for example it may be situated in a recess disposed in lower housing 310.

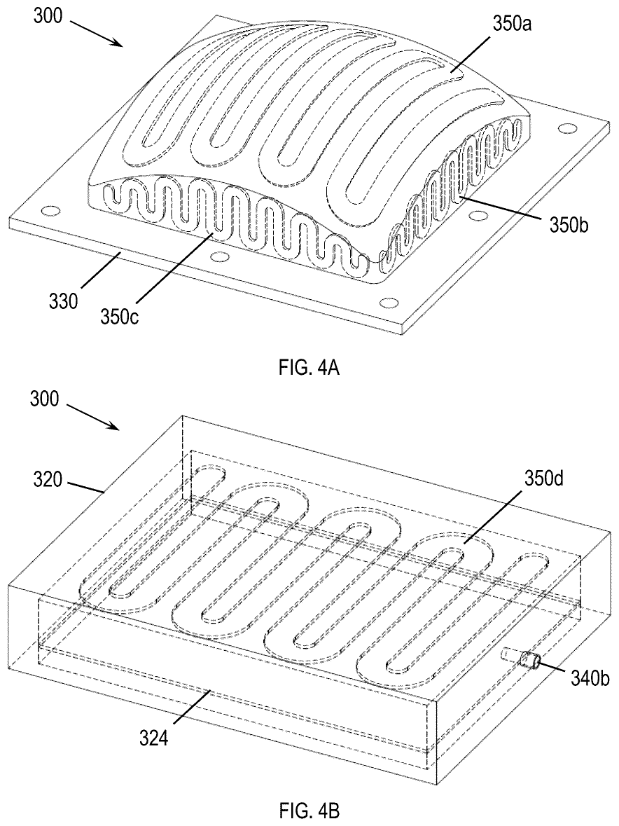

The mold 330, illustrated in FIG. 4A, may be further characterized by one or more heaters 350a, 350b, 350c. The heating elements 350a, 350b, 350c may couple and/or conform to the inner surfaces of the mold, which, in turn, match the surfaces of the solar panel 100 in an offset manner. The heating elements 350a, 350b, 350c may be continuous, or segmented into zones, as represented in FIG. 4A. Similarly, heating elements may be coupled to the surfaces not shown in FIG. 4A, i.e., surface opposite those surfaces upon which heating elements 350b, 350c are disposed. The heating elements 350a, 350b, 350c may be of one or more types, including electrical resistance heaters, fluid channel heaters, or infrared heaters. To facilitate a minimal thermal gradient across the laminate stack, one or more heating elements 350d may also be disposed in the upper housing 320, as shown in FIG. 4B. If the heating element is of the infrared radiation type, then the diaphragm 324 should be substantially transparent to such radiation. Alternatively, forced hot air may be used to heat the mold 330 and/or membrane 324 convectively, which then heats the laminate stack conductively.

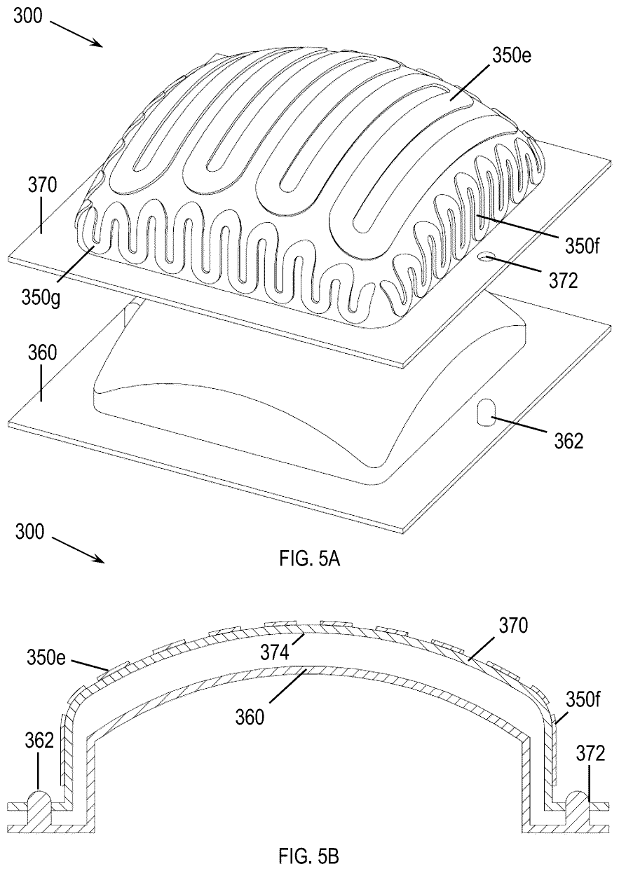

In general, for the purpose of facilitating minimal thermal gradients, heating elements, e.g., 350a, 350b, 350c, 350d may be integrated with or disposed upon any of the exemplary features illustrated in FIG. 5A. For example, elements may be disposed on or within the interior of lower housing 310, disposed on or within the mold 330, disposed on or within the lower tray 360, disposed on or within the upper tray 370, and/or disposed on or within the upper housing 320. Power may be supplied to said one or more heating elements in any suitable manner, such as via cables (not shown) configured to enter lower chamber 310 through the seal 314, or via electrical feedthroughs and cables that are routed through the lower and/or upper housing 310, 320, or via a power source coupled to the lamination stack that sits within the lower chamber 310 during the lamination processes. Additionally, the heating elements 350 may be any type of heating element that convects, conducts, and/or radiates heat to the lamination stack, including but not limited to: resistive heating elements, forced hot air, fluidic heating channels, and infrared radiation (IR) lamps.

### Lamination Trays

In addition to the laminator 300 comprising a mold 360, lift pins 316 and upper and lower heating elements 320, 310, of FIGS. 3A and B, lamination trays may provide advantages for the improved assembly, handling, lamination, production integration, automation, control and yield of doubly-curved (and flanged) solar panels. FIG. 5B illustrates representative lower tray 360 and upper tray 370, wherein either or both tray 360, 370 may be employed. During fabrication solar panels 100 are vulnerable to damage due to particulates and other foreign matter in the laminator as well as imperfections in the tooling of the laminator itself, e.g. scratches or dings in the mold. Also, handling of the components before and after lamination is a concern due to potential damage to the components and/or the finished panel. Furthermore, solar cells 210 are delicate and easily damaged during the curved forming process. Consequently, trays 360, 370, may be used to mitigate these and other problems. In particular, the trays 360, 370, may serve to: support the lamination components prior to lamination; reduce or eliminate damage from handling of the solar panel 100 components, e.g., preforms; convey the laminate stack as it is being assembled; align the various components of the stack during assembly; protect the stack from imperfections in the laminator environment and/or tooling; allow for even distribution of the temperature and pressure of the lamination process; allow for gentle and controlled curving of the solar cells during lamination; impart a controlled surface finish on the laminated panel; reduce or eliminate damage from handling of the finished solar panel 100; facilitate loading/unloading of the laminator 300; help protect the lamination equipment from flash from the encapsulant; and provide an interface for a release layer to be inserted or a surface upon which a release agent may be disposed.

Referring to FIGS. 5A and 5B, lower and upper lamination trays 360, 370 may have an offset shape corresponding to the bottom and top surfaces, respectively, of the laminate stack. The trays 360, 370, may be made from any suitable, material such as, for example metal, stiff polymer, or glass. Metal tray 360, 370, materials may include aluminum, steel, stainless steel, etc. Metal trays 360, 370, may be formed by any suitable process, such as, for example, stamping, milling, hydroforming, or machining. The surface finish of the metal trays 360, 370, may be formed by any suitable process, such as machining, polishing, abrasive-blasting, or etching. Polymer trays 360, 370, may be formed by any suitable process, such as molding or extruding and thermoforming. Glass trays 360, 370, may be molded or formed from sheet glass by any suitable process, such as by pressure forming or sag forming. A texture may be imparted on the superstrate-facing surface of the upper tray for the purpose of transferring said texture to the superstrate during lamination.

The upper tray 370 may be of an offset shape from the lower tray 360 which accounts for the final thickness of the laminated panel, as illustrated in FIG. 5B. Referring to FIG. 5A, the trays 360, 370 may further comprise a means of alignment between them, which may take the form of fiducials, features or datums. In this embodiment, alignment is achieved by means of pins 362 and holes 372 disposed in the lower tray 360 and upper tray 370, respectively. If the substrate 120 and superstrate 130 preforms extend to the tray flanges, then matching holes may also be disposed therein. Alternatively, printed, embossed, debossed or machined fiducials may be used to achieve alignment between two or more components of the laminate stack, such as, for example, between the lower tray 360 and the substrate 120. Another alternative is to achieve proper alignment through the use of datums, such as the vertical surfaces of any pair of elements that couple in the laminate stack. For example, edge or corner surfaces may be used to align any two or more elements, either by integral or external abutments. Finally, the upper tray 370 may be configured to impart a texture, such as an anti-reflective texture, to the outer facing surface of the solar panel. In this approach, a texture is applied to the downfacing surface 374 of the upper tray 370 and transfers to the superstrate 130 under the influence of pressure and heat.

In alternative embodiments, one or more of the mold 330, and/or trays 360, 370, may be omitted from the configuration shown. In an alternate embodiment, the mold 330 may be integrated with the lower housing 310. In yet another embodiment, the upper tray 370 may be integrated with one or more upper pistons to form a pressure element. Similarly, the laminator 300 described herein may be configured to accept a lamination stack having any arrangement of components. The arrangement shown in FIG. 5A, for example, shall not be a limitation thereto.

### Stack/Tray Alignment

The alignment of solar panel 100 component layers is important both when assembling the lamination stack and during the lamination process.

Superstrate/substrate misalignment can lead to oversizing of the panel and a poor fit within edging, frames and other higher-level assemblies. Furthermore, during the lamination process alignment must be maintained between the components of the lamination stack and between the lamination stack and the lower tray 360 or mold 330. Shifting of the superstrate 130 relative to the substrate can expose the encapsulant leading to moisture ingress along the non-overlapped edge. Finally, shifting of the entire lamination stack relative to the tray 360, 370 or mold 330 can lead to undesirable panel asymmetry or distortion.

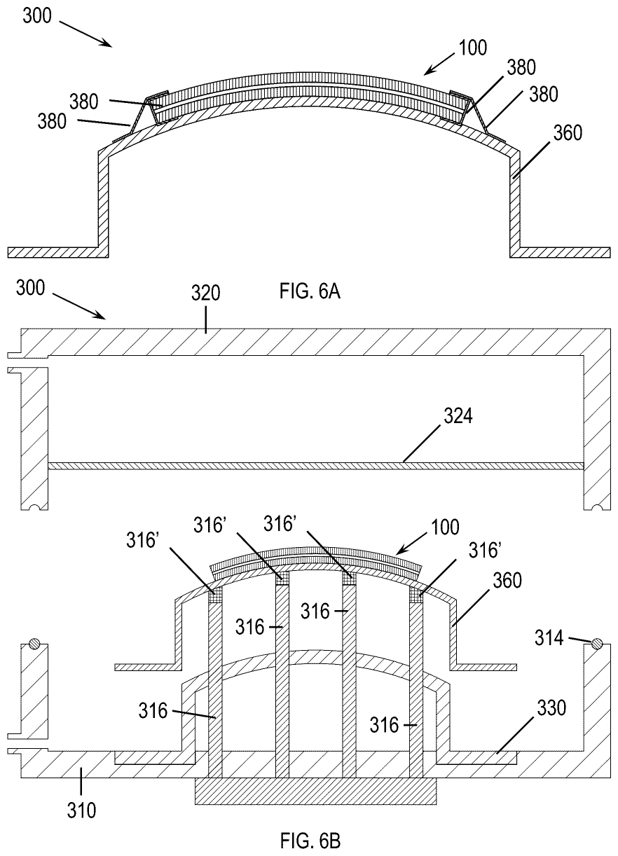

In order to prevent shifting of the lamination stack components once they have been aligned and assembled, a temporary binder in the form of adhesive tape 380 may be applied to the edges of the lamination stack, as shown in FIG. 6A. The tape 380 may preferably be thin, compressible and able to withstand the lamination temperature. For example, a polyimide-based tape, such as Kapton® may be used. In order to prevent shifting of the aligned, assembled and taped lamination stack relative to the lower tray 360 or mold 330, the same adhesive tape 380 may be used between the stack and the tray 360, also shown in FIG. 6A. After lamination both sets of tape 380 are removed from the panel 100. The adhesive of the tape 380 is preferably residue-free and leaves a clean panel surface.

The tape 380 method can be implemented manually and represents a proven alignment solution, for example, in low-volume production. Automation of the method, or other solutions must be developed for high-volume production. In high-volume production, printed, embossed or other marking method fiducials coupled with machine vision may be used for critical alignment of components where datums are not easily incorporated, such as the solar cell array. Where component datums do exist, such as the substrate or superstrate edges, passive alignment is preferred. While this may be good for the lamination stack assembly process, an additional challenge appears when the components are heated in the lamination chamber. Maintaining alignment between the lamination stack and tray requires accommodation for expansion or contraction of the panel relative to the tray. For polymer substrates and superstrates, for example, the panel 100 will expand significantly relative to an aluminum tray, e.g., 360, 370. For glass substrate 120 and superstrate 130, on the other hand, the panel 100 will contract relative to an aluminum tray, e.g., 360, 370. Consequently, a viable solution will be compliant to such expansion or contraction while at the same time providing a centering force to keep the panel 100 aligned with the tray 360, 370 or mold 330.

### Lift Pins

Loading and unloading of the lamination chamber may be facilitated by one or more lift pins 316 as shown in FIG. 6B. During the loading operation, in one embodiment, an array of pins 316 may be employed to raise the stack above the surface of the mold 330 to accept and pre-align the lower tray 360 and lamination stack to the mold 330. The array of pins 316 array may provide clearance for a forklift-style loading cart or robotic end effector. Unloading of the hot laminated panel 100 may similarly be facilitated. The lift pins 316 also facilitate controlled heating of the tray and lamination stack, which are at ambient temperature when loaded. Heating is preferably controlled by thermal conduction through the mold 330. However, material selection of the lift pins 316 can be modified as metal is sufficiently thermally conductive to raise the temperature of the tray 360 and lamination stack at the contact points, even in the raised state, and such temperature increase may be enough to initiate local curing of the encapsulant layers, resulting in non-uniform curing of the panel 100. Consequently, material selection may include thermally insulating materials, such as glass, ceramic, porous or fibrous materials.

To prevent thermal communication between the lift pins 316 and the lamination stack, a thermally insulating material may be disposed on a portion 316′ of the pins 316 that protrude from the mold 330, e.g. the tips 316′, as shown in FIG. 6B. Alternatively, the thermally insulating material 316′ may be disposed between the tip and the lift pin shaft at an elevation above the mold surface 330. The material preferably is configured to withstand the elevated temperatures of the lamination process and may be chosen from a group of a high temperature polymers such as, for example, polyetheretherketone (PEEK), which has a melting temperature of 343° C. Other thermally insulating materials may be used, such as glass, ceramic, porous or fibrous materials, etc. without limitation. The length of insulating material substituted for the tip of the pins 316 determines the total thermal resistance between pin 316 and tray 360. The thermal resistance, in turn, must be sufficient to reduce the temperature of the encapsulation layers to prevent premature curing, but so high as to form a cold spot when the tray 360 is in contact with the mold 330.

### General Operation

FIGS. 7A-7D describe the general operation of the laminator 300 for producing a doubly-curved solar panel 100. In a first view, shown in FIG. 7A, the laminator 300 is loaded with a laminate stack. To enable the loading step the lower chamber 312 is opened by separating the upper housing 320 from the lower housing 310 by the vertical lift method. Alternatively, the upper housing 320 may be opened by the hinged clamshell method (see FIG. 3B). The laminate stack may be loaded into the lower housing 310 manually or robotically. The laminate stack, shown here in an exploded view, is received in the lower chamber 312 by lift pins 316a, 316b which hold the stack above the preheated mold 330. The laminate stack may comprise, from bottom to top, a lower tray 360, a substrate 120, a lower encapsulant 112a, a solar cell array 200 comprising a at least one solar cells 210, an upper encapsulant 112b, a flanged superstrate preform 130, and an upper tray 370. The mold 330 may be heated by one or more heating elements 350a, 350b disposed therein. The upper chamber 322 may be also fitted with one or more heating elements 350d. In addition to facilitating loading, the lift pins 316a, 316b serve to prevent uncontrolled heating of the laminate stack during the loading process. Alignment of the laminate stack may be achieved by way of the flanged superstrate 130 and one or more alignment pins 362 disposed on the lower tray 360. Complementary holes 138, 372 may be disposed in the superstrate preform 130 and upper tray 370, respectively.

In a second view, given in FIG. 7B, the lift pins 316a, 316b may be retracted into the lower housing 310 of the laminator 300 thereby lowering the laminate stack onto the mold 330. The lower tray 360 is preferably of a shape that promotes good thermal contact between the tray 360 and the mold 330. In this view the laminate stack appears in its as assembled, collapsed state where the one or more alignment pins 362 of the lower tray 360 engage the openings 138, 372 of the superstrate 130 and upper tray 370, respectively. Note that, because the cells 210 of the solar cell array 200 are generally stiff and flat, an air gap may appear between the substrate 120 and superstrate 130 and between the superstrate 130 and lower tray 360. Next, the upper housing 320 is urged toward the lower housing 310 thereby sealing the lower chamber 312 with the aid of the O-ring 314. O-ring 314 may be a gasket or any other type of seal purposed to seal the lower chamber 312 to allow the formation of a vacuum. Both lower and upper chambers 312, 322 are evacuated through the vacuum ports 340a, 340b, respectively, thereby removing any air between the layers of the laminate stack. Because there is no pressure differential between lower and upper chambers 312, 322, the diaphragm 324 remains relaxed. Simultaneous with the evacuation of the chambers 312, 322, heat is applied to the laminate stack by means of the one or more heating elements 350a, 350b, 350d disposed in the mold 330 and/or upper housing 320.

In a third view, illustrated in FIG. 6C, the vacuum is released from the upper chamber 322 through the vacuum port 340b and the diaphragm 324 flexes into the lower chamber. The membrane 324 engages the upper tray 370 and applies pressure to the elements of the laminate stack, e.g., elements 360, 120, 110, 130, 370. Alternatively, if the upper tray 370 is omitted, the membrane 324 may engage the superstrate 130 directly. In any such alternative, the laminate stack is held under the appropriate conditions of vacuum, heat and pressure for the prescribed curing time of the laminates.

In a fourth view, illustrated in FIG. 7D, the vacuum in the lower chamber 312 may be released through the vacuum port 340a and the diaphragm 324 returns to its relaxed position. Next, the upper housing 320 is separated from the lower housing 310 thereby opening the lower chamber 312. Finally, the lift pins 316a, 326b raise the laminated stack, e.g., 360, 100, 370 to the unload position. At this point, the laminated stack may be removed from the laminator 300 either manually or robotically.

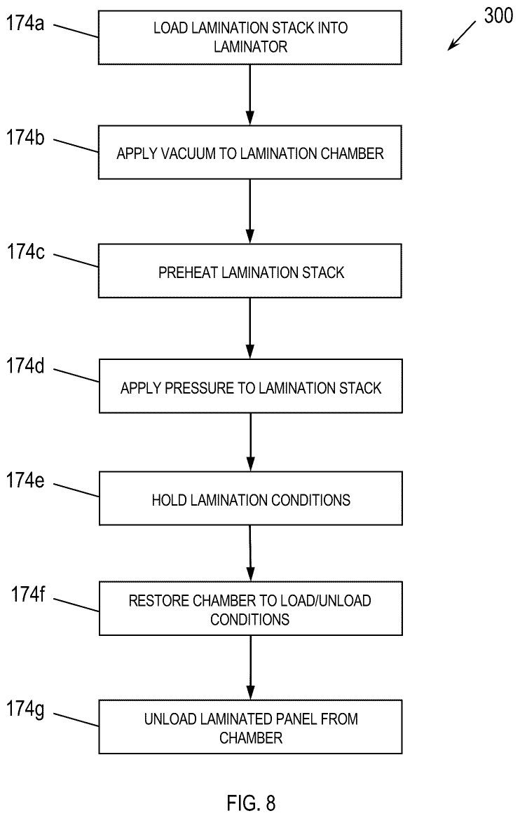

As illustrated by FIGS. 7A-7D and 8, the total cycle time of the laminator 300 may be defined as the time between when one stack enters the laminator 300, and when the next stack enters the laminator 300. Thus, the cycle time is an important factor related to the overall efficiency of the manufacturing plant that produces the solar panel 100, such as continuous lamination plant 400 of patent application Ser. No. 18/168,274. By way of example, in one approach considered within the scope of this disclosure, for each cycle, the lamination stack sits within the laminator 300 for approximately 15 to 20 minutes, comprising the steps of: (i) evacuation to achieve a vacuum, wherein the curing/heating may be considered to have initiated, lasting about 1-3 minutes; (ii) pressurization and curing/heating for the remaining time, for a total cycling time of about 15-20 minutes. By way of another example, a 12-minute cycle time may be achieved, the latter part involves a combined heating and pressurization state of the lamination stack lasting about 6 minutes.

FIG. 8 gives an exemplary flowchart for use of the laminator 300. The steps may include: a Step 174a, loading the lamination stack including trays, if present, into the lower chamber of the laminator 300; a Step 174b, closing the lid and evacuating air from lower and upper chambers 312, 322, so as to remove the same from between the layers of the lamination stack; a Step 174c, preheating the lamination stack; a Step 174d applying pressure to the lamination stack by suitable methods, such as mechanical pressure through the use of a piston or by way of a pressure differential applied to a diaphragm 324; a Step 174e holding the lamination conditions, i.e., chamber pressure, stack temperature, and diaphragm pressure, for a suitable interval; a Step 174f restoring the chambers 312, 322, to the loading/unloading conditions, e.g., atmospheric pressure, loading/unloading temperature, and relaxed diaphragm; and a Step 174g removing the laminated stack, including trays 360, 370, from the lower chamber of laminator 300.

### Mold Geometry and Panel Edge Effects

The mating of the membrane with the curved surfaces of the lamination stack and tray or mold is critical to the successful fabrication of a durable and reliable curved solar panel 100. In the discussion of FIGS. 5A through 8B, the terms “mold” 330 and “tray” 360 are interchangeable. In a flat laminator, the membrane is typically positioned close to the lamination stack. Upon increasing the pressure above the membrane, it flexes downward and makes initial contact at the center of the lamination stack. The contact area expands with increasing pressure until the entire panel is in contact with the membrane.

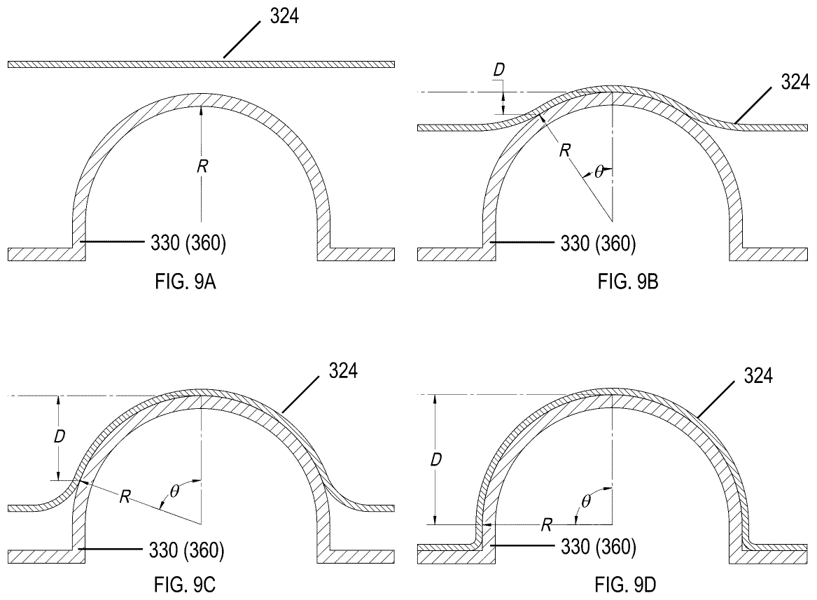

In a laminator with a curved mold, e.g., 330, the process is more complex. FIGS. 9A-9D illustrate the deformation of the membrane 324 and interaction with a mold of radius R as the pressure on the membrane 324 is increased. With no pressure the membrane 324 is unflexed, as shown in FIG. 9A. In FIG. 9B, as the pressure is raised to an intermediate value, the membrane 324 contacts the center of the mold and the contact point progresses to a contact angle, θ. Because the membrane 324 is fixed at the edges the membrane 324 becomes increasingly stretched with distance from the center. In FIG. 9C, additional pressure forces the membrane 324 further down the sides of the mold increasing the contact angle. Finally, in FIG. 9D, the pressure has forced the membrane 324 into complete contact with the mold 330, including vertical faces.

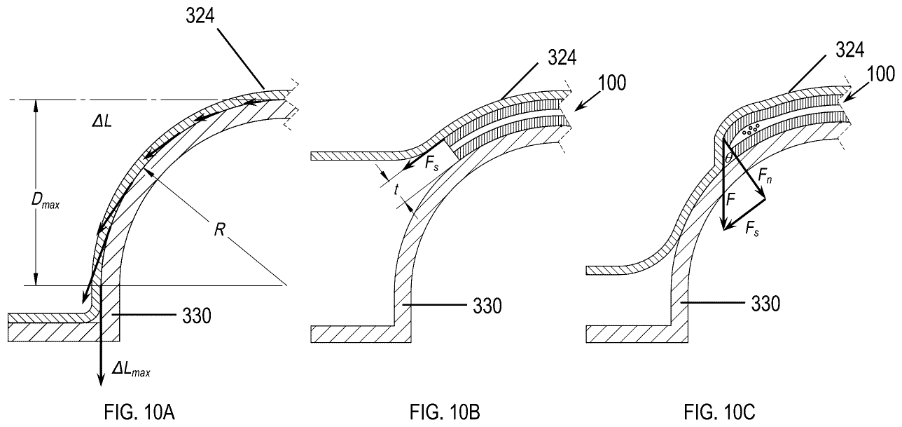

As in a flat laminator, at the contact point of the membrane 324 becomes fixed due to friction. Unlike in a flat laminator, when the membrane 324 wraps around a curved surface, the membrane displacement, D, may be significantly larger and θ can change significantly, where D varies as sin θ and at the initial point of contact D=0 by definition. The fixing of the membrane 324 at the mold 330 interface and the vertical displacement of the membrane 324 cause the membrane 324 to stretch by an increasing amount as it progresses down the sides of the mold 330. This creates an elongation or strain, ΔL, that increases with θ, as depicted in FIG. 10A. The maximum strain, ΔLₘₐₓ, occurs at the vertical surface of the mold, θ=90°, and is proportional to the maximum displacement, Dₘₐₓ. The strain varies from ΔL=ΔLₘₐₓ at θ=90° to ΔL=0 at θ=0° and follows the relation, ΔL=ΔLₘₐₓ sin θ. In other words, the strain is zero at the first point of contact (ignoring membrane displacement up to that point) and progresses non-linearly to its maximum at θ=90°. The strain in the unsupported portion of the membrane 324 is constant and equivalent to that of the contact point.

For curved solar panels 100 disposed on the mold 330 and directly contacted by the membrane 324, the lamination stack thickness, t, must be taken into account. FIG. 10B illustrates the case of a laminate stack disposed on the mold 330 of FIG. 10A wherein an intermediate amount of pressure has been applied. The membrane 324 fully contacts the panel and flexes a small amount beyond the panel edge. At the edge of the curved panel a reactionary shear force, Fₛ, appears and is equal to the product of the elastic modulus of the membrane and ΔL. Therefore, Fₛ ∝D. In other words, the greater the pressure required for the membrane 324 to contact the edge of the panel, the greater the magnitude of Fₛ. Since Fₛ is tangent to the surface of the superstrate, no normal force is applied. However, with additional pressure the membrane 324 flexes down across the vertical gap between the lamination stack and the mold surface, turning the direction of the force, F, downward as shown in FIG. 10C. In this orientation F has non-zero components in both the shear (Fₛ) and normal (Fₙ) directions. As before, Fₛ is of little consequence for the stiff superstrate 130. However, Fₙ is now acting as a localized pressure on the edge of the panel. Because the encapsulant layers of the core 110 are soft at the lamination temperature, the superstrate 130 may move in response to Fₙ. This results in a pinching of the core 110 forcing some of the encapsulant away from the edge and forming a bow in the superstrate 130 near the edge. In other words, the core at the panel edge experiences high pressure while a relatively low-pressure zone appears within the panel core adjacent to the edge. This has the effect of (i) reducing or preventing outgassing from the edge of the panel and (ii) allowing bubbles to accumulate in the low-pressure zone. Aside from the cosmetic degradation, the non-uniform lamination presents a reliability hazard. To summarize, an interaction between the lamination stack thickness, the mold geometry, and the membrane 324 can produce a non-uniform pressure. Specifically, as the displacement of the membrane 324 at the panel edge increases, the lamination stack gets thicker, and the exit angle of the membrane 324 from the panel edge becomes more perpendicular to the panel tangent, the larger the bending moment on the panel edge during lamination.

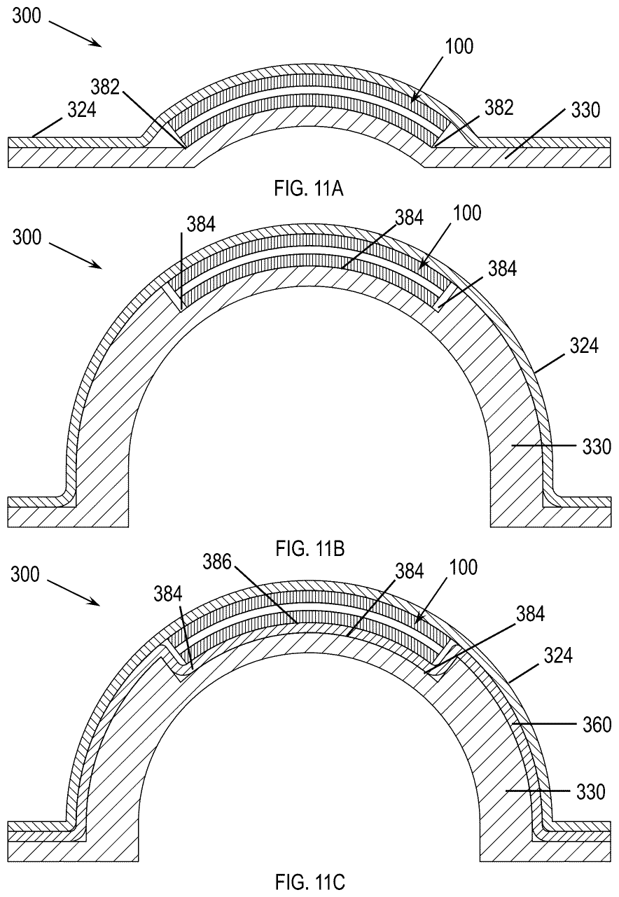

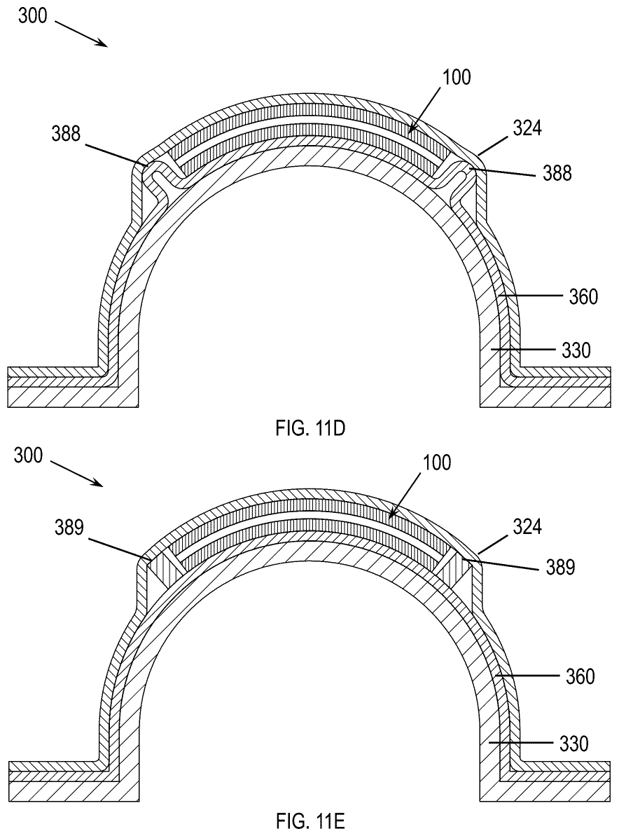

In a first solution to this problem, shown in FIG. 11A, the angle of the membrane 324 near the edge of the panel is changed from sub-tangent to tangent or super-tangent 382. This is accomplished via the shape of the mold 330 near the panel edge. In this embodiment, when the membrane 324 reaches the edge of the panel it is prevented from turning downward by the obtuse angle of the mold 330 with respect to the panel surface tangent. This keeps F substantially coincident with the panel tangent thereby reducing or eliminating Fₙ and so preventing pinching, bowing and bubble formation within the panel.

In an alternative embodiment, given in FIG. 11B, a recess 384 may be formed, e.g., machined, in the mold 330 with a depth equal to the thickness of the laminated panel. In this context, substantially equal refers to being within manufacturing tolerances. As the lamination stack is compressed, the top of the superstrate becomes flush with, or substantially level with, the adjacent mold 330 surface. Even with a small gap between the panel and mold, the membrane 324 does not deflect significantly, thereby keeping F substantially coincident with the panel 100 tangent.

In another embodiment, illustrated in FIG. 11C, a recess 386 may be formed in the tray 360, such as, for example, via a stamping process. A matching recess 384 may be formed (e.g. machined) into the mold 330, thereby allowing for the required thermal contact with the tray 360. As the lamination stack is compressed, the top of the superstrate 130 becomes flush with the adjacent tray 360 surface. Even with a small gap between the panel 100 and tray 360, the membrane 324 does not deflect significantly, thereby keeping F substantially coincident with the panel tangent and minimizing or eliminating Fₙ.

In another embodiment, illustrated in FIG. 11D, a riser 388 may be formed within the tray 360, such as for example, via a stamping process. The riser 388, which forms a border around the lamination stack, such as a contiguous perimeter, facilitates the lifting of the membrane to proximate the level of the superstrate 130 surface keeping Fₛ in line with the panel tangent. This approach has the advantage of allowing for a recess-free mold 330 surface.

In another embodiment, illustrated in FIG. 11E, a riser 389 may be formed in the tray, such as for example, via an assembly process. The riser 389 may be formed or machined separately and secured to the tray 360 or mold 330 by adhesive, fasteners, soldering, brazing or other attachment method, depending on the material used. The riser 389, which forms a border around the lamination stack, such as a contiguous perimeter, facilitates lifting of the membrane 324 to proximate the level of the superstrate 130 surface keeping F in line with the panel tangent. This approach has the advantage of allowing for a recess-free mold 330 surface.

Mold and/or Tray Alignment

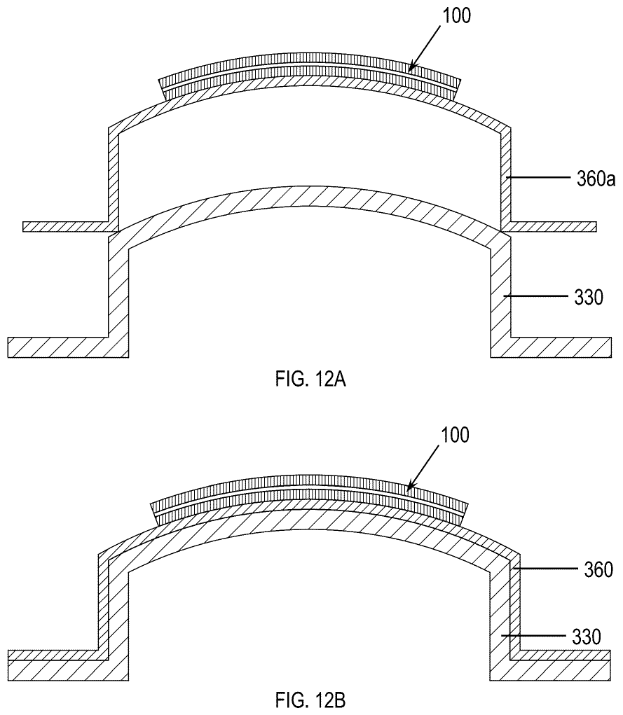

Referring now to FIGS. 12A and 12B, molds 330 and trays 360, e.g., 360a and 360b are generally precision fabricated to share a matching interface in order to transfer heat from the mold to the tray via thermal conduction. Any gap existing between the mold 330 and tray 360 can cause heat to be transferred through convection, which is much less efficient than conduction. Consequently, incomplete physical contact between the mold 330 and the tray 360 can lead to non-uniform heating within the lamination stack. Heating non-uniformities, in turn, can lead to under- or over-curing of the encapsulant, incomplete out-gassing and bubble formation, poor edge adhesion, delamination and/or other panel failure modes. For these reasons, it is desirable that the mold 330 and tray 360 be mechanically coupled to provide uniform conduction, preferably throughout the lamination process, but especially at the lamination temperature. However, in a standard lamination process, the mold 330 is generally kept at or slightly above the lamination temperature while the tray 360 and lamination stack are assembled at ambient temperature. This temperature difference may be as much as about 135° C. Assuming that the mold 330 and tray 360a are made of the same material, such as aluminum, thermal expansion will cause the mold 330 to increase dimensionally relative to the tray, as illustrated in FIG. 12A. Here, a mold 330 and tray 360a combination having vertical sidewalls and which mate properly at room temperature, now exhibit interference when the mold 330 is at an elevated temperature and the tray 360a is at about room temperature. Only when the tray 360 reaches the temperature of the mold 330, as shown in FIG. 12B as tray 360b, does the tray 360 mate properly with the mold 330.

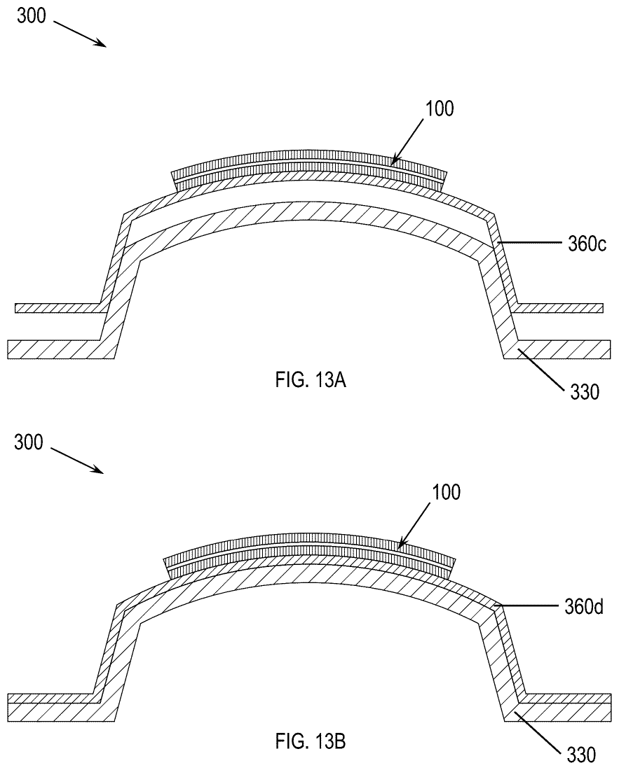

To solve this problem two approaches are provided. In a first approach, illustrated in FIGS. 13A and 13B, the sides of the mold 330 and tray 360 are angled to form a stacking configuration. In FIG. 13A the cold tray 360, shown representatively as tray 360c is lowered onto the hot mold 330. Since the mold 330 has expanded relative to the tray 360c, the tray 360c cannot fully seat on the mold 330, thereby leaving a small but uniform gap between the upper portions, such as proximate the lamination stack. In this configuration, a uniform convective heating may be applied to the upper portion of the tray 360c proximate the lamination stack holding the lamination stack. As the tray 360c heats up it gradually expands and slowly slides down over the mold 330 under the influence of gravity. When the tray 360 reaches the temperature of the mold 330, shown representatively as tray 360d in FIG. 13B, it achieves complete contact with the mold 330. This process is controllable and reproducible and therefore suitable for manufacturing.

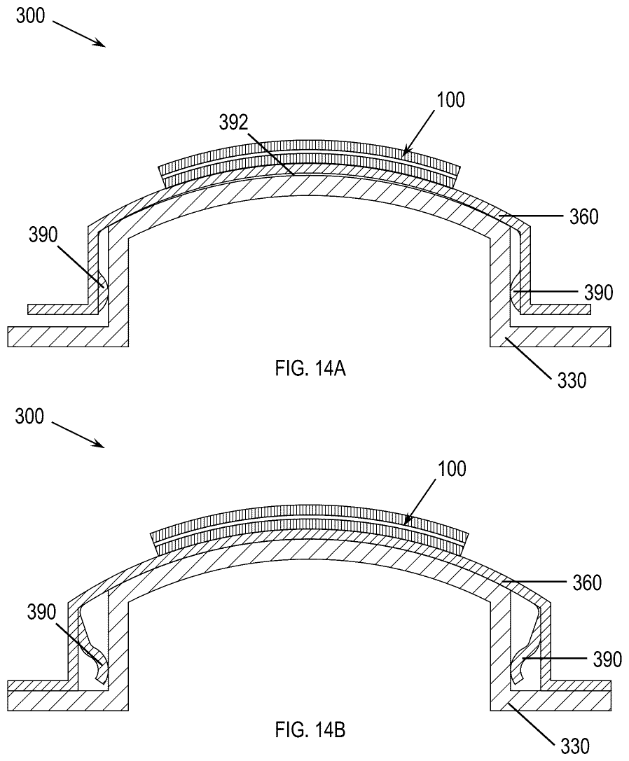

In a second approach, shown in FIGS. 14A and 14B, a tray fitted with compliant features 390 may be disposed on or formed into the mold 330. Referring to FIG. 14A, the vertical sidewalls of the tray 360 provide clearance for the mold 330 when the tray 360 is cold. Compliant elements 390, for example in the form of stamped biasing elements 390, may contact the vertical sides of the mold 330 and center the tray 360 with respect to the mold 330. In the cold state of the tray 360 the biasing elements 390 are maximally flexed. The curvature of the upper portion of the tray 360 preferably matches that of the mold 330 at a common temperature. However, when the mold 330 is hot and the tray 360 is cold, the radius of curvature of the tray 360 is smaller than that of the mold 330. Thus, a small gap 392 appears between the upper portions of the tray 360 and the mold 330. Advantageously, this gap 392 is very small and has only a minor effect on the heating of the tray 360. As the tray 360 temperature increases, the tray 360 expands and the biasing elements 390 contract to maintain the mold/tray alignment. In a hot state the biasing elements 390 of the tray 360 are minimally flexed and the curvature of the tray 360 and mold 330 are equal as shown in FIG. 14B. Since the tray 360 is very close to or in contact with the mold 330 throughout the temperature cycle, the process is driven mostly by the temperature of the mold, which is precisely controlled.

### Membrane Strain

Because curved molds 330 and/or trays 360 occupy a greater chamber volume than flat lamination surfaces the membrane 324 must be positioned further from the platen or bottom extent of the mold 330 in order to provide clearance for the mold 330, tray 360 and lamination stack. This, in turn, requires that the membrane expand a greater amount relative to a flat laminator membrane in order to conform to the curved mold and apply pressure to the complete laminate stack. The greater displacement gives rise to high membrane stress which can lead to membrane failure resulting in laminator down time and increased production costs and considerations of the chamber further comprises sharp corner and edge geometries causing the membrane 324 to stretch locally to conform to these features.

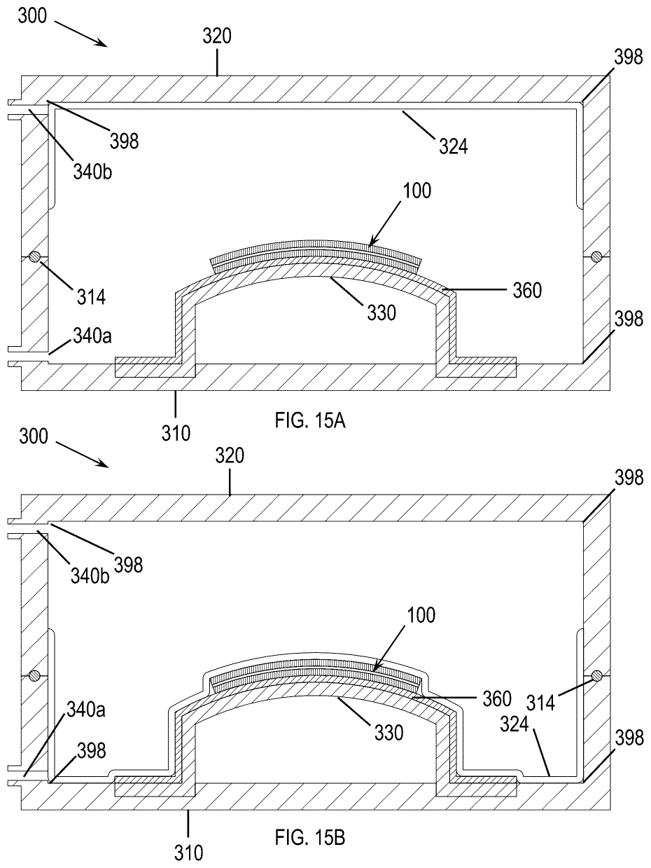

FIGS. 15A and 15B illustrate an example of a chamber with right-angle corner and edge features 398. In FIG. 15A the membrane 324 has been pulled into the lid using vacuum in order to provide clearance for the loaded lamination stack. In this position, the maximum stress points of the membrane 324 are located at the corners 398 of the upper chamber. In FIG. 15B the membrane 324 has been pulled into the lower chamber using vacuum in order to provide pressure during the lamination process. While some higher stress points may form around the mold 330, these occur at an intermediate value of membrane 330 elongation as the last surfaces to be contacted coincide with the maximum membrane elongation. It has been found that membrane failure may occur at these points after a reduced number of pressurization cycles. Thus, the maximum stress points of the membrane 330 are located at the corners 398 of the lower chamber.

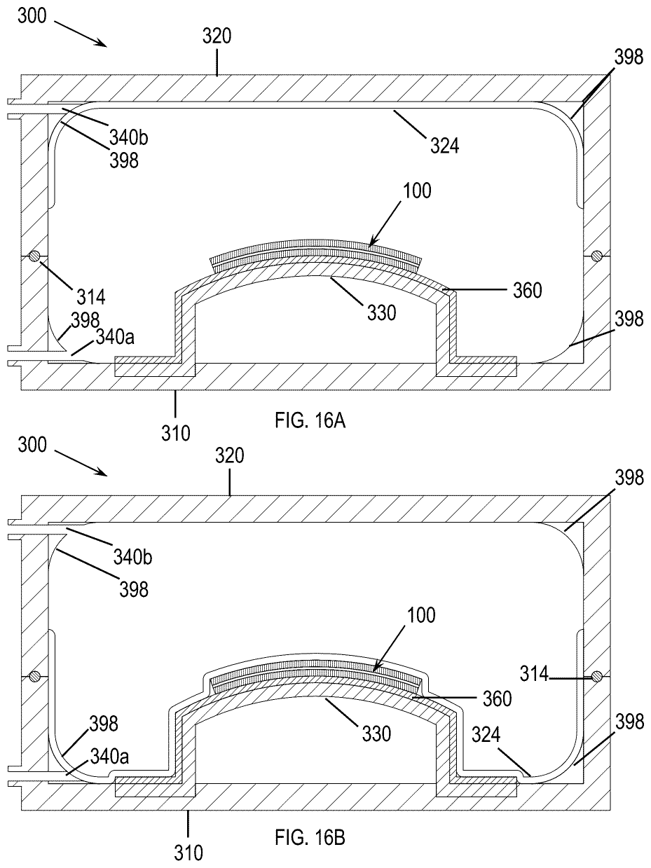

To solve this problem two approaches are provided. In a first approach, illustrated in FIGS. 16A and 16B, the edges and corners of the chambers are chamfered 399, filleted or otherwise made less sharp. The fillets 399 may be formed in the housing by a fabrication process, such as machining. Alternatively, the fillet features 399 may be fabricated separately, as by for example 3D printing, and later assembled into the chamber. In FIG. 16A the membrane has been pulled into the lid using vacuum in order to provide clearance for the loaded lamination stack. In FIG. 16B the membrane has been pulled into the lower chamber using vacuum in order to provide pressure during the lamination process. In FIGS. 16A and 16B the fillets serve to increase the radius of curvature of the stretched membrane 324 thereby spreading the stress over a greater area and reducing its magnitude. The reduction in maximum stress experienced by the membrane 330 increases number of pressure cycles before failure, improving laminator throughput and reducing cost.

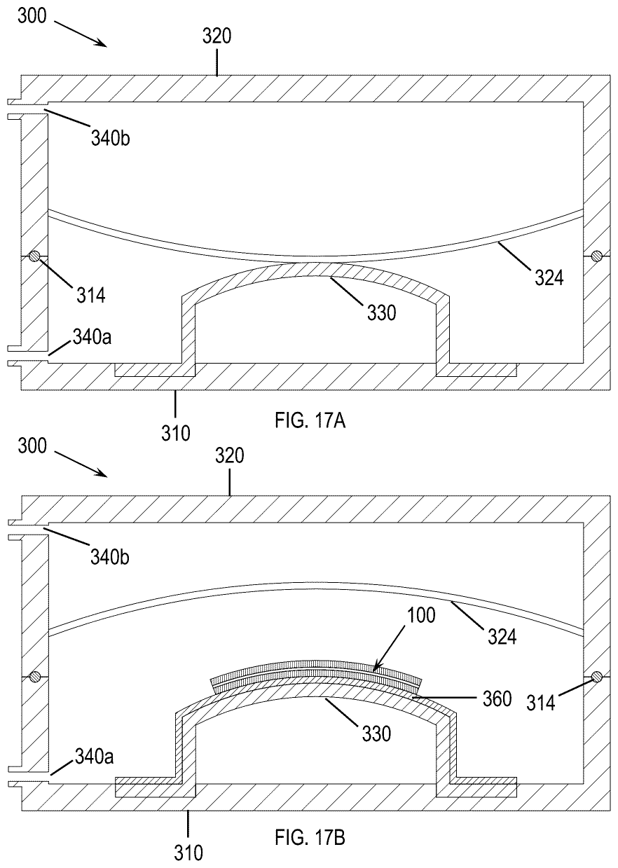

In a second approach, shown in FIGS. 17A and 17B, the amount of tension present in the relaxed state of the membrane 324 is reduced by introducing slack. FIG. 17A exhibits a slack membrane 324 in a closed housing with only the mold 330 present. The membrane 324 may rest above the mold 330 and/or otherwise come into contact with the mold 330, depending on its position in the lid and the amount of slack present. FIG. 17B shows the loaded laminator wherein a slight vacuum has been applied to the upper chamber to lift the slack membrane 324 into the lid and provide clearance for the lamination stack. Upon pressurization during the lamination process, as shown in FIG. 17B, the initially slack membrane has a shorter distance to travel in order to fill the lower chamber, thereby reducing membrane strain.

### Vents

During the lamination process the encapsulant material releases volatile byproducts in a process called outgassing. However, in a curved laminator 300, the membrane 324 may enclose and temporarily seal the lamination stack against the mold 330 or tray 360, thus preventing some gasses from escaping. This can cause under-curing of the encapsulant. Under certain conditions, trapped gasses may form bubbles within the encapsulant layer. Aside from the cosmetic degradation, the sub-optimum lamination presents performance and reliability hazards, such as low transparency, poor edge adhesion, delamination and other panel failure modes.

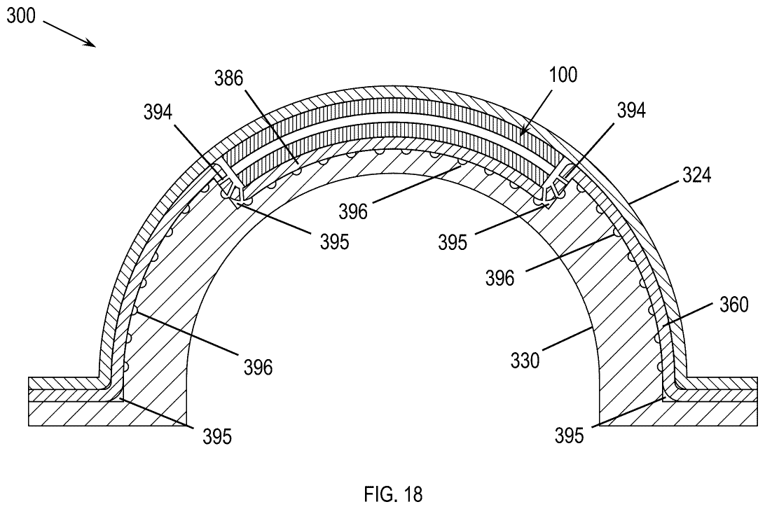

Referring to FIG. 18, to prevent trapping of gasses during the pressure phase of the lamination process, passages, such as holes, vents and channels may disposed on the tray and/or mold, represented as passages 394 and 396, respectively. During the pressure phase outgassing occurs almost exclusively from the edge of the panel. Therefore, gas escape routes are advantageously formed at the panel perimeter. FIG. 16 follows the example of FIG. 11C wherein a stamped tray 360 and recessed mold 330 are used to prevent membrane-induced stresses at the edge of the panel 100. In this embodiment, vent holes 394 may be formed in the tray 360, such as in the walls of the stamped recess 386. Evacuation channels 395 in fluid communication with the lower chamber vacuum via opening 340a may be formed between the tray 360 and the mold 330, for example, between a stamped tray 360 fillet and a machined corner of the mold recess 386. If additional collection channels 396 are required, they may be machined into the mold 330 in the form of grooves. The grooves 396 may have a variety of profiles including, but not limited to, rectangular, square, v-shaped, ovular, and/or circular, or any shape configured to achieve the desired purpose of exfiltrating said vapor. Grooves 396 may be disposed at a variety of angles, such as, for example, perpendicular and/or parallel to the plane of the page, or other non-perpendicular angle as many equivalent configurations exist that satisfy the requirements of (i) an inlet disposed in proximity to the panel edge and (ii) an outlet in communication with the lower chamber vacuum.

### Postamble

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

1. A laminator system comprising:
a lower housing including a convex surface having two axes of curvature, said convex surface selected from the group consisting of: a mold, a lower tray, or said lower tray being operably coupled to said mold in a physically and thermodynamically complementary manner,
said convex surface being adapted to uniformly transfer heat from a heat source to, and to support, a lamination stack when said lamination stack is coupled thereto,
said convex surface including a protrusion formed outwardly therefrom and formed contiguous a perimeter of said lamination stack when said lamination stack is coupled to said convex surface, and
said convex surface further including one or more passages formed proximate said perimeter of said lamination stack when said lamination stack is operably coupled to said convex surface, said one or more passages adapted to convey a vapor away from said lamination stack during lamination;
one or more lift pins adapted to move said lamination stack between a first position and a second position,
said first position characterized by said lamination stack being offset from said heat source such that said lamination stack is thermally insulated from said heat source,
said second position characterized by said lamination stack being in thermal communication with said heat source, and
said one or more lift pins including a thermally insulative portion such that when said one or more pins are in said first position, said thermally insulative portion of said one or more pins thermally insulate said lamination stack from said heat source; and
an upper housing including a membrane having a first membrane portion proximate said lamination stack and a second membrane portion surrounding said first membrane portion;
wherein said protrusion is shaped such that, when said membrane is in a lamination state, said first membrane portion is coincident with, or forms a obtuse angle with respect to, said second membrane portion about said perimeter,
wherein, in an assembled configuration said lower and upper housing form a cavity partitioned by said membrane to form upper and lower cavities, said upper cavity having at least one radiused upper corner and an upper opening formed in said upper housing to remove and/or add fluid to said upper cavity, said lower cavity having at least one radiused lower corner and a lower opening formed in said lower housing to remove and/or add fluid to said lower cavity.

2. A laminator system comprising:
a lower housing including a convex surface having two axes of curvature, said convex surface selected from the group consisting of: a mold, a lower tray, or said lower tray being operably coupled to said mold in a physically and thermodynamically complementary manner,
said convex surface being adapted to uniformly transfer heat from a heat source to, and to support, a lamination stack when said lamination stack is coupled thereto, and
said convex surface including a protrusion formed outwardly therefrom and formed contiguous a perimeter of said lamination stack when said lamination stack is operably coupled to said convex surface;
one or more lift pins adapted to move said lamination stack between a first position and a second position,
said first position characterized by said lamination stack being offset from said heat source such that said lamination stack is thermally insulated from said heat source, and
said second position characterized by said lamination stack being in thermal communication with said heat source; and
an upper housing including a membrane;
wherein, in an assembled configuration said lower and upper housing form a cavity partitioned by said membrane to form upper and lower cavities, said upper cavity having an upper opening formed in said upper housing to remove and/or add fluid to said upper cavity, said lower cavity having a lower opening formed in said lower housing to remove and/or add fluid to said lower cavity.

3. The laminator system according to claim 2, wherein said convex surface is said mold, and said protrusion is selected from the group consisting of: formed by a super-tangent angle, and formed by a recess formed into said mold, said recess having a depth substantially equal to a thickness of said lamination stack.

4. The laminator system according to claim 2, wherein said convex surface is said lower tray being operably coupled to said mold in a physically and thermodynamically complementary manner, and said protrusion is formed by a recess formed into said lower tray, said recess having a depth substantially equal to a thickness of said lamination stack.

5. The laminator system according to claim 2, wherein said convex surface is said lower tray being operably coupled to said mold in a physically and thermodynamically complementary manner, and said protrusion is selected from the group consisting of: formed by a raised portion of said lower tray and formed by an object mounted to said lower tray.

6. The laminator system according to claim 5, said upper cavity further having a plurality of radiused upper corners and said lower cavity further having a plurality of radiused lower corners, said radiused upper and lower corners being adapted to reduce stress on said membrane by reducing the elongation thereof.

7. The laminator system according to claim 6, said one or more lift pins including a thermally insulative portion such that when said one or more pins are in said first position, said thermally insulative portion of said one or more pins thermally insulate said lamination stack from said heat source.

8. The laminator system according to claim 7, said convex surface further including one or more passages formed proximate said perimeter of said lamination stack when said lamination stack is operably coupled to said convex surface, said one or more passages adapted to convey a vapor away from said lamination stack during lamination.

9. The laminator system according to claim 8, wherein said lower tray being operably coupled to said mold in a physically and thermodynamically complementary manner further comprises a draft angle ranging from greater than zero degrees to about 30 degrees.

10. The laminator system according to claim 9, wherein said lower tray comprises at least one set of opposing biasing elements adapted to maintain alignment of said tray to said mold when said one or more are moved from said first position to said second position and/or when said heat source begins transferring heat.

11. A method of laminating a solar panel comprising the steps of:
providing the laminator system according to claim 2;
providing said lamination stack comprising a substrate, a superstrate, and a core disposed therebetween, said core including a solar array having at least one solar cell surrounded by an encapsulant;
supplying a first vacuum to said upper chamber, thereby deforming said membrane such that it conforms to said the upper chamber;
moving said one or more lift pins to said first position;
superposing said lamination stack proximate said convex surface and coupling said lamination stack to said one or more lift pins;
moving said upper housing and/or said lower housing to said assembled configuration;
supplying a second vacuum to said lower chamber;
moving said lift pins to said second position and applying uniform transfer of heat from said heat source to said lamination stack;
maintaining said second vacuum to said lower chamber while said lamination stack reaches a lamination temperature;
releasing said first vacuum from said upper chamber, thereby deforming said membrane such that pressure is applied to said lamination stack and said at least one solar cell of said solar array moves along to axes of curvature;
maintaining said lamination stack within said pressure, uniform transfer of heat, and said second vacuum for a predetermined amount of time to form a laminated panel;
releasing said second vacuum thereby moving said membrane to a neutral position;
removing said heat source;
disassembling said upper housing and said lower housing;
moving said one or more lift pins to said first position;
removing said laminated panel from said laminator system.

12. The method of laminating a solar panel according to claim 11 further comprising the step of removably securing said superstrate to said substrate with adhesive tape.

13. The method of laminating a solar panel according to claim 12, further comprising the step of removably securing said lamination stack to said lower tray with adhesive tape.
